(19) United States
(12) Patent Application Publication
(10) Pub. No.: US 2023/0290831 A1
(43) Pub. Date: Sep. 14, 2023

(54) TRANSISTOR ARRANGEMENTS WITH REDUCED DIMENSIONS AT THE GATE

(71) Applicant: Intel Corporation, Santa Clara, CA (US)

(72) Inventors: Abhishek A. Sharma, Hillsboro, OR (US); Wilfred Gomes, Portland, OR (US); Ravi Pillarisetty, Portland, OR (US); Willy Rachmady, Beaverton, OR (US); Sagar Suthram, Portland, OR (US); Pushkar Sharad Ranade, San Jose, CA (US); Anand S. Murthy, Portland, OR (US); Tahir Ghani, Portland, OR (US)

(73) Assignee: Intel Corporation, Santa Clara, CA (US)

(21) Appl. No.: 17/690,358

(22) Filed: Mar. 9, 2022

(51) Int. Cl. H01L 29/10; H01L 29/45; H01L 29/06; H01L 29/423; H01L 29/40

(52) U.S. Cl. CPC H01L 29/1033; H01L 29/45; H01L 29/0665; H01L 29/42392; H01L 29/401; H01L 27/10826

(57) ABSTRACT

The scaling of features in ICs has been a driving force behind an ever-growing semiconductor industry. As transistors of the ICs become smaller, their gate lengths become smaller, leading to undesirable short-channel effects such as poor leakage, poor subthreshold swing, drain-induced barrier lowering, etc. Reducing transistor dimensions at the gate allows keeping the footprint of the transistor relatively small and comparable to what could be achieved implementing a transistor with a shorter gate length while effectively increasing transistor's effective gate length and thus reducing the negative impacts of short-channel effects. This architecture may be optimized even further if transistors are to be operated at relatively low temperatures, e.g., below 200 Kelvin degrees or lower.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each contact becomes increasingly significant. Careful design of transistors, e.g., field-effect transistors (FETs), may help with such an optimization.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example IC device implementing a nanoribbon-based transistor arrangement with reduced dimensions at the gate, in accordance with some embodiments.

FIG. 2A-2C provide cross-sectional side views and a top-down view of an IC device implementing nanoribbon-based transistor arrangement with reduced dimensions at the gate, in accordance with some embodiments.

FIG. 3A-3C provide cross-sectional side views of an IC device implementing a memory cell that includes a nanoribbon-based transistor arrangement with reduced dimensions at the gate, in accordance with different embodiments.

FIG. 4 provides a perspective view of an example IC device implementing fin-based transistor (FinFET) arrangement with reduced dimensions at the gate, in accordance with some embodiments.

FIG. 5A-5C provide cross-sectional side views and a top-down view of an IC device implementing FinFET arrangement with reduced dimensions at the gate, in accordance with some embodiments.

FIG. 6A-6B provide cross-sectional side views of an IC device implementing a memory cell that includes a FinFET arrangement with reduced dimensions at the gate, in accordance with different embodiments.

FIG. 7 is a high-level cross-sectional side view of an IC device assembly with transistor layers configured for operation at different temperatures, in accordance with some embodiments.

FIG. 8 is a flow diagram of an example method of manufacturing an IC device with one or more transistor arrangements with reduced dimensions at the gate, in accordance with some embodiments.

FIG. 9 provides top views of a wafer and dies that include one or more transistor arrangements with reduced dimensions at the gate in accordance with any of the embodiments disclosed herein.

FIG. 10 is a cross-sectional side view of an IC package that includes an IC device with one or more transistor arrangements with reduced dimensions at the gate in accordance with any of the embodiments disclosed herein.

FIG. 11 is a cross-sectional side view of an IC device assembly that includes an IC device with one or more transistor arrangements with reduced dimensions at the gate in accordance with any of the embodiments disclosed herein.

FIG. 12 is a block diagram of an example computing device that includes an IC device with one or more transistor arrangements with reduced dimensions at the gate in accordance with any of the embodiments disclosed herein.

FIG. 13 is a block diagram of an example processing device that includes an IC device with one or more transistor arrangements with reduced dimensions at the gate in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating transistor arrangements with reduced dimensions at the gate and associated devices and systems as described herein, it might be useful to first understand phenomena that may come into play in certain transistor arrangements. The following foundational information may be viewed as a basis from which the present disclosure may be properly explained. Such information is offered for purposes of explanation only and, accordingly, should not be construed in any way to limit the broad scope of the present disclosure and its potential applications.

As described above, the scaling of features in ICs has been a driving force behind an ever-growing semiconductor industry. As transistors of the ICs become smaller (i.e., as their footprints are reduced), their gate lengths become smaller. However, reducing gate lengths of transistors leads to undesirable short-channel effects such as poor leakage, poor subthreshold swing, drain-induced barrier lowering, etc. Embodiments of the present disclosure are based on recognition that reducing transistor dimensions at the gate allows keeping the footprint of the transistor relatively small and comparable to what could be achieved implementing a transistor with a shorter gate length while effectively increasing transistor's effective gate length and thus reducing the negative impacts of short-channel effects. More specifically, reducing transistor dimensions at the gate refers to reducing a width and/or a thickness/height of a channel portion of a transistor to be less than about 90%, e.g., less than about 85% or less than about 80%, of the corresponding dimension (i.e., a width and/or a thickness/height) of a source region or a drain region of a transistor. Embodiments of the present disclosure are further based on recognition that transistor arrangements with reduced dimensions at the gate may be optimized even further if transistors are to be operated at relatively low temperatures, where, as used herein, low-temperature operation (or “lower-temperature” operation) refers to operation at temperatures below room temperature, e.g., below 200 Kelvin degrees or lower. Thermal energy is much lower at low temperatures and, consequently, the off-current (Ioff) of a transistor is much lower and the subthreshold swing is much sharper, compared to room temperature operation. Consequently, if a transistor is operated at low temperatures, its gate length can be shorter than what can be achieved at room temperatures, while keeping the short-channel effects at a level that does not significantly compromise transistor performance. As a result, at low temperatures, it may be possible to further decrease footprints of transistor arrangements with reduced dimensions at the gate, thereby decreasing their effective gate lengths, while still maintaining adequate performance.

In the following detailed description, various aspects of the illustrative implementations may be described using terms commonly employed by those skilled in the art to convey the substance of their work to others skilled in the art. For example, as is known in the art, a “channel portion” of a transistor (also sometimes referred to as a “channel region”) is a portion of a channel material of a transistor on which a transistor gate is provided, with a source region and a drain region provided within the channel material on either side of the channel portion, thus forming a FET. If a transistor has a non-planar architecture (e.g., if a transistor is a nanoribbon-based transistor or a FinFET), then the transistor gate may at least partially wrap around the channel portion. The terms “channel material” and “channel layer” may be used interchangeably, as well as the terms “transistor” and “transistor arrangement.” Since, as is common in the field of FETs, designations of “source” and “drain” are often interchangeable, source and drain regions of a transistor may be referred to as first and second source or drain (S/D) region, where, in some embodiments, the first S/D region is a source region and the second S/D region is a drain region and, in other embodiments, this designation of source and drain region is reversed. Analogous applies to S/D contacts of a transistor. The term “width” of a channel material, a source region, or a drain region refers to a dimension measured along a line that is perpendicular to a direct line between the source region and the drain region in a plane substantially parallel to a support structure (e.g., a substrate, a die, a wafer, or a chip) over which the transistor arrangement is built. On the other hand, the terms “thickness” and “height” of a channel material, a source region, or a drain region refers to a dimension measured along a line substantially perpendicular to the support structure, where the term “thickness” may be more appropriate for nanoribbon-based transistors, while the term “height” may be more appropriate for FinFETs, even though they refer to the same dimensions. As used herein, the term “connected” means a direct electrical or magnetic connection (e.g., a direct contact) between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, analogous elements designated in the present drawings with different reference numerals after a dash, e.g., dimensions 156-1 and 156-2 indicative of reductions in width on opposite sides of a channel portion may be referred to together without the reference numerals after the dash, e.g., as “width reductions 156.” In order to not clutter the drawings, if multiple instances of certain elements are illustrated, only some of the elements may be labeled with a reference sign.

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of transistor arrangements with reduced dimensions at the gate as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various transistor arrangements with reduced dimensions at the gate as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

In various implementations of transistor arrangements with reduced dimensions at the gate, the channel material may be of any suitable geometry, enabling forming transistors of planar architectures or non-planar architectures. Transistors of planar architectures may include silicon-on-insulator (SOI) transistors, single-gate transistors, double-gate transistors, thin-film transistors (TFTs), and so on. Transistors of non-planar architectures may include fin-based FETs (FinFETs), nanoribbon transistors, nanowire transistors, and so on. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors. Therefore, transistor arrangements with reduced dimensions at the gate are explained herein with reference to two examples of non-planar transistors—nanoribbon-based transistors and FinFETs.

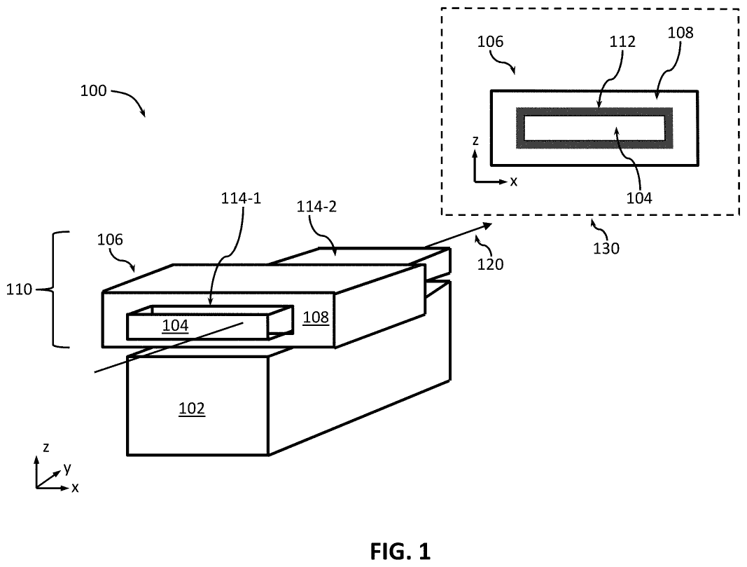

Nanoribbon-based transistors may be particularly advantageous for continued scaling of complementary metal-oxide-semiconductor (CMOS) technology nodes due to the potential to form gates on all four sides of a channel material (hence, such transistors are sometimes referred to as “gate all-around” transistors). FIG. 1 provides a perspective view of an example IC device 100 implementing a nanoribbon-based transistor arrangement with reduced dimensions at the gate, in accordance with some embodiments. The transistor arrangement of the IC device 100 is one example of a transistor arrangement with reduced dimensions at the gate.

Turning to the details of FIG. 1, the IC device 100 may include a semiconductor material, which may include one or more semiconductor materials, formed as a nanoribbon 104 extending substantially parallel to a support structure 102. The transistor 110 may be formed on the basis of the nanoribbon 104 by having a gate stack 106 at least partially wrap around a portion of the nanoribbon referred to as a “channel portion” and by having source and drain regions, shown in FIG. 1 as a first S/D region 114-1 and a second S/D region 114-2, on either side of the gate stack 106. In some embodiments, a layer of oxide material (not specifically shown in FIG. 1) may be provided between the support structure 102 and the gate stack 106.

The IC device 100 shown in FIG. 1, as well as IC devices shown in other drawings of the present disclosure, is intended to show relative arrangements of some of the components therein, and the IC device 100, or portions thereof, may include other components that are not illustrated (e.g., electrical contacts to the S/D regions 114 of the transistor 110, additional layers such as a spacer layer around the gate stack 106 of the transistor 110, etc.). For example, although not specifically illustrated in FIG. 1, a dielectric spacer may be provided between a first S/D contact coupled to a first S/D region 114-1 of the transistor 110 and the gate stack 106 as well as between a second S/D contact coupled to a second S/D region 114-2 of the transistor 110 and the gate stack 106 in order to provide electrical isolation between the source, gate, and drain contacts (in general, “contacts” described herein may also be referred to as “electrodes”). In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

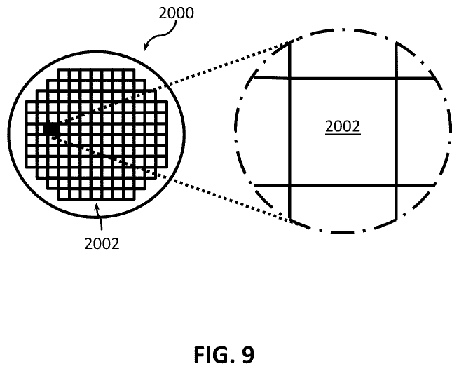

Implementations of the present disclosure may be formed or carried out on any suitable support structure 102, such as a substrate, a die, a wafer, or a chip. The support structure 102 may, e.g., be the wafer 2000 of FIG. 9, discussed below, and may be, or be included in, a die, e.g., the singulated die 2002 of FIG. 9, discussed below. The support structure 102 may be a semiconductor substrate composed of semiconductor material systems including, for example, N-type or P-type materials systems. In one implementation, the semiconductor substrate may be a crystalline substrate formed using a bulk silicon or a SOI substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support structure 102 may be a printed circuit board (PCB) substrate. Although a few examples of materials from which the support structure 102 may be formed are described here, any material that may serve as a foundation upon which an IC device with one or more transistor arrangements with reduced dimensions at the gate as described herein may be built falls within the spirit and scope of the present disclosure.

The nanoribbon 104 may take the form of a nanowire or nanoribbon, for example. In some embodiments, an area of a transverse cross-section of the nanoribbon 104 (i.e., an area in the x-z plane of the example coordinate system x-y-z shown in the present drawings) may be between about 25 and 10000 square nanometers, including all values and ranges therein (e.g., between about 25 and 1000 square nanometers, or between about 25 and 500 square nanometers). The transverse cross-section of the nanoribbon 104 is cross-section along a plane perpendicular to a longitudinal axis 120 of the nanoribbon 104, where the longitudinal axis 120 may, e.g., be along the y-axis of the example coordinate system shown in the present drawings. In some embodiments, a width of the nanoribbon 104 (i.e., a dimension measured in a plane parallel to the support structure 102 and in a direction perpendicular to the longitudinal axis 120, e.g., along the x-axis of the example coordinate system shown in the present drawings) may be at least about 3 times larger than a thickness (or a “height”) of the nanoribbon 104 (i.e., a dimension measured in a plane perpendicular to the support structure 102, e.g., along the z-axis of the example coordinate system shown in the present drawings), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

The nanoribbon 104 may be formed of one or more semiconductor materials, together referred to as a “channel material,” where some examples of the channel materials that may be used in transistor arrangements with reduced dimensions at the gate are described below with reference to a channel material 105.

A gate stack 106 including a gate electrode material 108 and, optionally, a gate insulator 112, may wrap entirely or almost entirely around a portion of the nanoribbon 104 as shown in FIG. 1, with the channel portion of the transistor 110 being the active region (channel region) of the channel material in the portion of the nanoribbon 104 wrapped by the gate stack 106. The gate insulator 112 is not shown in the perspective drawing of the IC device 100 shown in FIG. 1 but is shown in an inset 130 of FIG. 1, providing a cross-sectional side view of a portion of the nanoribbon 104 with a gate stack 106 wrapping around it. As shown in FIG. 1, the gate insulator 112 may wrap around a transversal portion of the nanoribbon 104, and the gate electrode material 108 may wrap around the gate insulator 112.

The gate electrode material 108 may include at least one P-type work function metal or N-type work function metal, depending on whether the transistor 110 is a P-type metal-oxide-semiconductor (PMOS) transistor or an N-type metal-oxide-semiconductor (NMOS) transistor (P-type work function metal used as the gate electrode material 108 when the transistor 110 is a PMOS transistor and N-type work function metal used as the gate electrode material 108 when the transistor 110 is an NMOS transistor). For a PMOS transistor, metals that may be used for the gate electrode material 108 may include, but are not limited to, ruthenium, palladium, platinum, cobalt, nickel, and conductive metal oxides (e.g., ruthenium oxide). For an NMOS transistor, metals that may be used for the gate electrode material 108 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 108 may include a stack of two or more metal layers, where one or more metal layers are work function metal layers and at least one metal layer is a fill metal layer. Further layers may be included next to the gate electrode material 108 for other purposes, such as to act as a diffusion barrier layer or/and an adhesion layer.

In some embodiments, the gate insulator 112 may include one or more high-k dielectrics including any of the materials discussed herein with reference to the insulator material that may surround portions of the transistor 110. In some embodiments, an annealing process may be carried out on the gate insulator 112 during manufacture of the transistor 110 to improve the quality of the gate insulator 112. The gate insulator 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and source/drain contacts of the transistor 110 and could be made of a low-k dielectric material, some examples of which have been provided above. A gate spacer may include pores or air gaps to further reduce its dielectric constant.

In some embodiments, the gate insulator 112 may include a hysteretic material or a hysteretic arrangement, which, together, may be referred to as a “hysteretic element.” Transistors 110 in which the gate insulator 124 includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a voltage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator 112 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 112 may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for memory devices, such defects are desirable because charge-trapping may be used to represent different memory states of a memory cell.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D electrodes, although these regions may also have lower dopant concentrations and may form Schottky contacts in some implementations. Irrespective of the exact doping levels, the S/D regions of a transistor may be the regions having dopant concentration higher than in other regions, e.g., higher than a dopant concentration in the channel portion (i.e., in a channel material extending between the first S/D region 114-1 and the second S/D region 114-2), and, therefore, may be referred to as “highly doped” (HD) regions. The channel portion of the transistor 110 may include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

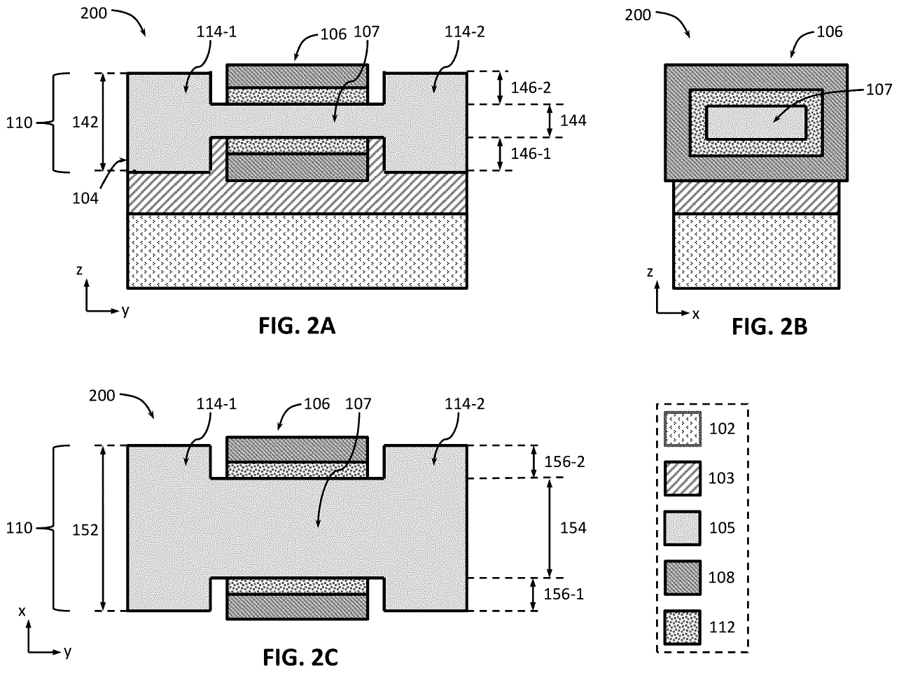

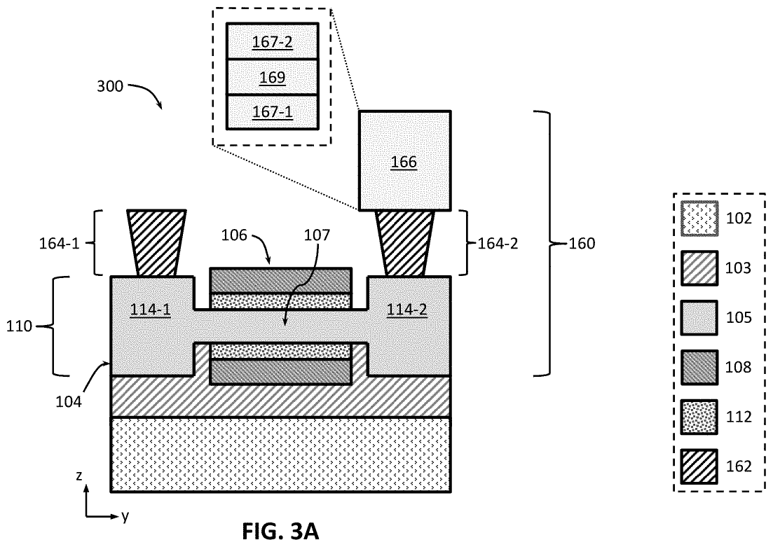

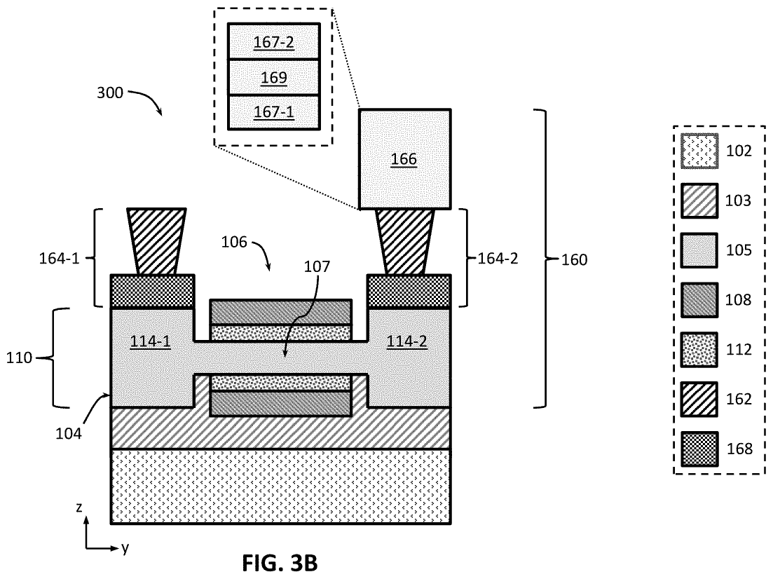

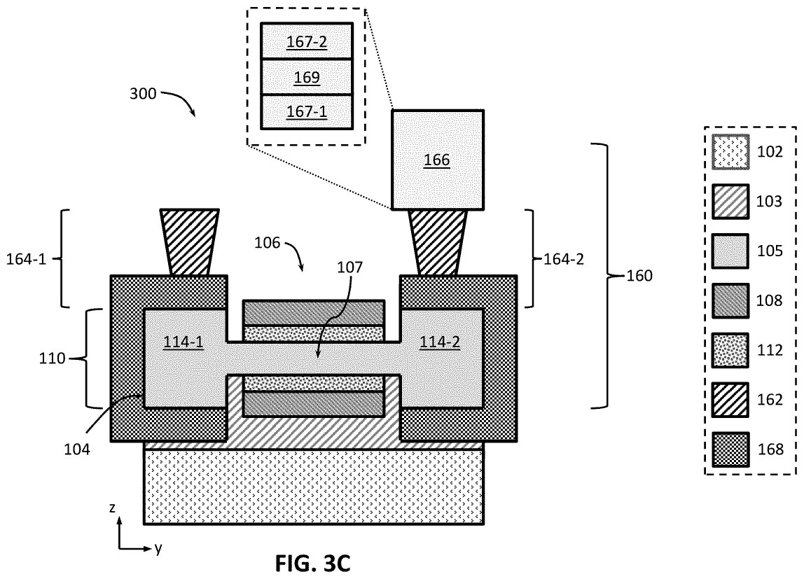

The nanoribbon 104 may form a basis for forming a nanoribbon-based transistor arrangement with reduced dimensions at the gate, the details of which are explained with reference to FIG. 2A-2C, providing cross-sectional side views and a top-down view of an IC device 200 implementing a nanoribbon-based transistor arrangement with reduced dimensions at the gate, in accordance with some embodiments. The IC device 200 may be an example of the IC device 100, shown in FIG. 1. To that end, FIGS. 2A-2C illustrate some of the same reference numerals as those shown in FIG. 1, to indicate similar or analogous elements as those that were described with reference to FIG. 1, so that description of those are not repeated for FIGS. 2A-2C. A number of elements labeled in FIGS. 2A-2C, as well in some of the subsequent drawings (e.g., FIGS. 3, 5, and 6) with reference numerals are indicated in these drawings with different patterns in order to not clutter the drawings with too many reference numerals, with a legend showing the correspondence between the reference numerals and patterns being provided to the right of FIG. 2C. For example, the legend illustrates that FIGS. 2A-2C use different patterns to show a support structure 102, an intermediate layer 103, a channel material 105, etc.

In some embodiments, the intermediate layer 103 may be a layer of an insulator material, e.g., a layer of oxide material described with reference to FIG. 1 as potentially being provided between the support structure 102 and the gate stack 106 but not specifically shown in FIG. 1. In general, the intermediate layer 103 may include any of the insulator materials, e.g., ILD materials, described above. In some embodiments, the intermediate layer 103 may be a layer with a plurality of frontend devices, e.g., frontend transistors, such as FinFETs, nanosheet transistors, nanoribbon transistors, nanowire transistors, or planar transistors. In some embodiments, the intermediate layer 103 may also include one or more backend layers, e.g., one or more backend memory layers. Details of the intermediate layer 103 are not shown because various manners for arranging various devices and interconnects are known in the art, all of which being within the scope of the present disclosure.

As shown in FIG. 2, the transistor 110 may be built based on a channel material 105, shaped as the nanoribbon 104, provided over the support structure 102, e.g., provided over the intermediate layer 103. In general, the channel material 105 may be composed of semiconductor material systems including, for example, N-type or P-type materials systems. In some embodiments, the channel material 105 may include a substantially monocrystalline semiconductor, such as silicon (Si) or germanium (Ge). In some embodiments, the channel material 105 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel material 105 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 105 may include a combination of semiconductor materials.

For some example N-type transistor embodiments (i.e., for the embodiments where the transistor 110 is an NMOS transistor), the channel material 105 may include a III-V material having a relatively high electron mobility, such as, but not limited to InGaAs, InP, InSb, and InAs. For some such embodiments, the channel material 105 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a PMOS transistor), the channel material 105 may advantageously be a group IV material having a high hole mobility, such as, but not limited to Ge or a Ge-rich SiGe alloy. For some example embodiments, the channel material 105 may have a Ge content between 0.6 and 0.9, and advantageously may be at least 0.7.

In some embodiments, the channel material 105 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel material 105 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel material 105 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, the transistor 110 may be a TFT. A TFT is a special kind of a FET made by depositing a thin film of an active semiconductor material over a support (e.g., the support structure 102) that may be a non-conducting support. Some such materials may be deposited at relatively low temperatures, which allows depositing them within the thermal budgets imposed on back end fabrication to avoid damaging the front end components such as the logic devices of an IC device 100. At least a portion of the active semiconductor material forms a channel of the TFT. In some such embodiments, the channel material 105 may be deposited as a thin film and may include any of the oxide semiconductor materials described above.

In other embodiments, instead of being deposited at relatively low temperatures as described above with reference to the TFTs, the channel material 105 may be epitaxially grown in what typically involves relatively high-temperature processing. In such embodiments, the channel material 105 may include any of the semiconductor materials described above, including oxide semiconductor materials. In some such embodiments, the channel material 105 may be epitaxially grown directly on a semiconductor layer of the support structure 102 over which the transistor 110 will be fabricated, in a process known as “monolithic integration.” In other such embodiments, the channel material 105 may be epitaxially grown on a semiconductor layer of another support structure and then the epitaxially grown layer of the channel material 105 may be transferred, in a process known as a “layer transfer,” to be over the support structure 102 of which the transistor 110 will be fabricated, in which case the latter support structure may but does not have to include a semiconductor layer prior to the layer transfer. Layer transfer advantageously allows forming non-planar transistors, such as FinFETs or all-around gate transistors such as nanowire or nanoribbon transistors, over support structures or in layers that do not include semiconductor materials (e.g., in the back end of an IC device). Layer transfer also advantageously allows forming transistors of any architecture (e.g., non-planar or planar transistors) without imposing the negative effects of the relatively high-temperature epitaxial growth process on devices that may already be present over a support structure.

The channel material 105 deposited at relatively low temperatures is typically a polycrystalline, polymorphous, or amorphous semiconductor, or any combination thereof. The channel material 105 epitaxially grown is typically a highly crystalline (e.g., monocrystalline or single-crystalline) material. Therefore, whether the channel material 105 is deposited at relatively low temperatures or epitaxially grown can be identified by inspecting grain size of the active portions of the channel material 105 (e.g., of the portions of the channel material 105 that form channels of transistors). An average grain size of the channel material 105 being between about 0.5 and 1 millimeters (in which case the material may be polycrystalline) or smaller than about 0.5 millimeter (in which case the material may be polymorphous or amorphous) may be indicative of the channel material 105 having been deposited (e.g., in which case the transistors in which such channel material 105 is included are TFTs). On the other hand, an average grain size of the channel material 105 being equal to or greater than about 1 millimeter (in which case the material may be a single-crystal material) may be indicative of the channel material 105 having been epitaxially grown and included in the final device either by monolithic integration or by layer transfer.

In still other embodiments, the channel material 105 may include one or more of so-called “two-dimensional (2D)” semiconductor materials such as graphene, molybdenum disulfide (MoS₂), tungsten disulfide (WS₂), black phosphorous, or other thin-film semiconductor materials. Such embodiments may be advantageous because bandgaps of 2D semiconductor materials may be modified relatively easy.

Although it is not seen in the perspective view of FIG. 1, the transistor 110 of the IC device 100 may be an arrangement with reduced dimensions at the gate. This is shown in FIG. 2 with the nanoribbon 104 having a thickness 142 in some areas but a thickness 144 in other areas, the thickness 144 being smaller than the thickness 142, e.g., less than about 90%, e.g., less than about 85% or less than about 80%, than the thickness 142. In some embodiments, the thickness 142 may be a thickness of the nanoribbon 104 in the areas of the S/D regions 114. As such, the thickness 142 may be referred to as a thickness of the S/D regions. However, in general, the thickness 142 may be the thickness of the nanoribbon 104 in all portions of the nanoribbon 104 except for the channel portions, where an example channel portion 107 of the transistor 110 is labeled in FIG. 2. Thus, the thickness 144 may be a thickness of the nanoribbon 104 in the channel portion 107. In some embodiments, the thickness 142 may be between about 1 and 75 nanometers, including all values and ranges therein, e.g., between about 3 and 50 nanometers or between about 5 and 30 nanometers. The thickness of the channel portion 107 may be reduced to the thickness 144 by means of a thickness reduction 146-1 at the bottom of the nanoribbon 104 (e.g., by removing a portion of the channel material 105 from the face of the nanoribbon 104 that is closest to the support structure 102) and/or a thickness reduction 146-2 at the top of the nanoribbon 104 (e.g., by removing a portion of the channel material 105 from the face of the nanoribbon 104 that is farthest away from the support structure 102). In some embodiments, the dimensions of the thickness reductions 146-1 and 146-2 may be substantially the same, as illustrated in FIG. 2. However, in other embodiments, the dimensions of the thickness reductions 146-1 and 146-2 may be different and one or both of the thickness reductions 146-1 and 146-2 may be absent (e.g., the thickness reductions 146-1 and 146-2 may be absent if reduced dimensions at the gate are achieved by means of only reducing the width of the nanoribbon at the channel portion 107).

Alternatively or additionally to having a reduced thickness, the transistor 110 of the IC device 100 may be an arrangement with reduced dimensions at the gate, as shown in FIG. 2 with the nanoribbon 104 having a width 152 in some areas but a width 154 in other areas, the width 154 being smaller than the width 152, e.g., less than about 90%, e.g., less than about 85% or less than about 80%, than the width 152. In some embodiments, the width 152 may be a width of the nanoribbon 104 in the areas of the S/D regions 114. As such, the width 152 may be referred to as a width of the S/D regions. However, in general, the width 152 may be the width of the nanoribbon 104 in all portions of the nanoribbon 104 except for the channel portions 107. Thus, the width 154 may be a width of the nanoribbon 104 in the channel portion 107. In some embodiments, the width 152 may be between about 1 and 75 nanometers, including all values and ranges therein, e.g., between about 3 and 50 nanometers or between about 5 and 30 nanometers. The width of the channel portion 107 may be reduced to the width 154 by means of a width reduction 156-1 at one sidewall of the nanoribbon 104 (e.g., by removing a portion of the channel material 105 from the first sidewall of the nanoribbon 104) and/or a width reduction 156-2 at another sidewall of the nanoribbon 104 (e.g., by removing a portion of the channel material 105 from the second sidewall of the nanoribbon 104). In some embodiments, the dimensions of the width reductions 156-1 and 156-2 may be substantially the same, as illustrated in FIG. 2. However, in other embodiments, the dimensions of the width reductions 156-1 and 156-2 may be different and one or both of the width reductions 156-1 and 156-2 may be absent (e.g., the width reductions 156-1 and 156-2 may be absent if reduced dimensions at the gate are achieved by means of only reducing the thickness of the nanoribbon at the channel portion 107).

As described above, the IC device 100 shown in the present drawings is intended to show relative arrangements of some of the components therein, and the IC device 100, or portions thereof, may include other components that are not illustrated. For example, while FIG. 2 illustrates only a single nanoribbon 104 provided over the support structure 102, in some embodiments, the IC device 100 may include a stack of nanoribbons 104, provided over one another over the support structure 104. In another examples, while FIG. 2 illustrates only a single transistor 110 implemented based on the nanoribbon 104, in some embodiments, the IC device 100 may include a plurality of transistors 110 implemented based on different portions of the nanoribbon 104.

In some embodiments, nanoribbon-based transistor arrangement with reduced dimensions at the gate may be implemented in memory arrays. In some such embodiments, a transistor with reduced dimensions at the gate may be coupled to a storage element, thus forming a 1T-1X memory cell of a memory array, where “1T” in the term “1T-1X memory cell” indicates that the memory cell includes one transistor (T), and where “1X” in the term “1T-1X memory cell” indicates that the memory cell includes one storage element (X). In other embodiments, a transistor with reduced dimensions at the gate may be coupled to multiple storage elements, or a transistor with reduced dimensions at the gate may be coupled to another transistor, to form one or more memory cells of a memory array, all of which being within the scope of the present disclosure. Generally, a storage element may be any suitable IC component that can be programmed to a target data state (e.g., corresponding to a particular charged stored on the storage element or corresponding to a particular resistance state of the storage element) by applying an electric field or energy (e.g., positive or negative voltage or current pulses) to the storage element for a particular duration. In various embodiments, a storage element may be a capacitor, a resistive storage element, a resistive random-access memory (RRAM) device, a metal filament memory device, a phase change memory (PCM) device, a magnetic random-access memory (MRAM) device, etc.

Some examples of 1T-1X nanoribbon-based memory are illustrated in FIG. 3A-3C, providing cross-sectional side views of an IC device 300 implementing a memory cell 160 that includes a nanoribbon-based transistor arrangement with reduced dimensions at the gate, in accordance with different embodiments. The IC device 300 may be an example of the IC device 200, shown in FIG. 2. To that end, FIGS. 3A-3C illustrate some of the same reference numerals as those shown in FIG. 2, to indicate similar or analogous elements as those that were described with reference to FIG. 2, so that description of those are not repeated for FIGS. 3A-3C.

As shown in FIGS. 3A-3C, the memory cell 160 may include the transistor 110 as described above, a first S/D contact 164-1, electrically coupled to (e.g., in electrical/direct contact with) the first S/D region 114-1, a second S/D contact 164-2, electrically coupled to (e.g., in electrical/direct contact with) the second S/D region 114-2, and a storage element 166, electrically coupled to the second S/D contact 164-2. In some embodiments, the storage element 166 may include two electrodes 167-1 and 167-2, separated by a memory material 169. One example of the electrodes 167 and the memory material 169 of the storage element 166 is schematically illustrated within the dashed contour shown in FIGS. 3A-3C, but, in other embodiments, the spatial arrangement of the memory material 169 and the electrodes 167 may be different as long as the memory material 169 is spatially between the electrode 167-1 and the electrode 167-2 (e.g., the memory material 169 does not have to be a planar layer but may be arranged in any kind of a three-dimensional arrangement). The memory material 169 may be any suitable material that can put into a target state by applying an electric field or energy (e.g., positive or negative voltage or current pulses) to one or both electrodes 167 of the storage element 166 for a particular duration, thus programming the storage element 166 to a target data state (e.g., corresponding to a particular charged stored on the storage element 166 or corresponding to a particular resistance state of the storage element 166). Such a storage element 166 may be electrically coupled to the second S/D contact 164-2 by coupling the electrode 167-1 of the storage element 166 to the second S/D contact 164-2 (e.g., in some embodiments, the electrode 167-1 of the storage element 166 and the second S/D contact 164-2 may be a shared contact of a suitable electrically conductive material).

As an example, a dynamic random-access memory (DRAM) cell may include a storage element 166 in a form of a capacitor for storing a bit value, or a memory state (e.g., logical “1” or “0”) of the cell, and an access transistor, implemented as the transistor 110 with reduced dimensions at the gate, controlling access to the cell (e.g., access to write information to the cell or access to read information from the cell). Such a memory cell may be referred to as a “1T-1C memory cell,” highlighting the fact that it uses one transistor (i.e., “1T” in the term “1T-1C memory cell”) and one capacitor (i.e., “1C” in the term “1T-1C memory cell”).

In another example, the storage element 166 may be a resistive storage element (also referred to herein as a “resistive switch”) that includes the memory material 169 that is a resistance-changing material, i.e., during operation the memory material 169 can be switched between two different nonvolatile states: a high resistance state (HRS) and a low resistance state (LRS). The state of a resistive storage element may be used to represent a data bit (e.g., logical “1” for HRS and logical “0” for LRS, or vice versa). A resistive storage element may have a voltage threshold beyond which the resistive storage element is in the LRS; driving a resistive storage element into the LRS may be referred to as SET (with an associated SET threshold voltage). Similarly, a resistive storage element may have a voltage threshold beyond which the resistive storage element is in the HRS; driving a resistive storage element into the HRS may be referred to as RESET (with an associated RESET threshold voltage).

In another example, the storage element 166 may be a RRAM device; in such embodiments, the memory material 169 may include an oxygen exchange layer (e.g., hafnium) and an oxide layer, as known in the art.

In yet another example, the storage element 166 may be a metal filament memory device (e.g., a conductive bridging random-access memory (CBRAM) device); in such embodiments, the memory material 169 may include a solid electrolyte, and one of the electrodes 167 of the storage element 166 may be an electrochemically active material (e.g., silver or copper), and the other of the electrodes 167 of the storage element 166 may be an inert material (e.g., an inert metal), as known in the art. A chemical barrier layer (e.g., tantalum, tantalum nitride, or tungsten) may be disposed between the electrochemically active electrode and the solid electrolyte to mitigate diffusion of the electrochemically active material into the solid electrolyte, in some such embodiments.

In some embodiments, the storage element 166 may be a phase change memory (PCM) device; in such embodiments, the memory material 169 may include a chalcogenide or other phase change memory material.

In some embodiments, the storage element 166 may be a MRAM device; in such embodiments, the memory material 169 may include a thin tunnel barrier material, and the electrodes 167 of the storage element 166 may be magnetic (e.g., ferromagnetic). As known in the art, MRAM devices may operate on the principle of tunnel magnetoresistance between two magnetic layers (e.g., the electrodes of the storage element 166) separated by a tunnel junction (e.g., the memory material of the storage element 166). An MRAM device may have two stable states: when the magnetic moments of the two magnetic layers are aligned parallel to each other, an MRAM device may be in the LRS, and when aligned antiparallel, an MRAM device may be in the HRS.

FIG. 3A illustrates an embodiment where a given S/D contact 164 may include only a contact metal 162. The contact metal 162 may include any metal, a metal alloy, or a stack of multiple metals, with metals such as copper, ruthenium, palladium, platinum, cobalt, nickel, hafnium, zirconium, titanium, tantalum, and aluminum. In some embodiments, contact metal 162 may include one or more electrically conductive alloys oxides or carbides of one or more metals. In such an embodiment, the contact metal 162 of a given S/D contact 164 may be in contact with the respective S/D region 114.

FIG. 3B illustrates an embodiment where the S/D contact 164 may include not only a contact metal 162 but also a doped semiconductor material 168, where the doped semiconductor material 168 of a given S/D contact 164 may be in contact with the respective S/D region 114, and where the contact metal 162 of a given S/D contact 164 may be in contact with the respective doped semiconductor material 168. The doped semiconductor material 168 may include any suitable semiconductor material that has been doped to be electrically conductive. For example, the doped semiconductor material 168 may include any of the semiconductor materials described above with reference to the channel material 105, but with the dopant concentration of at least about 5×10¹⁸ dopants per cubic centimeter, e.g., at least about 5×10¹⁹ dopants per cubic centimeter or at least about 1×10²¹ dopants per cubic centimeter. In some embodiments, the doped semiconductor material 168 may have a bandgap that is lower than that of the channel material 105, e.g., lower than about 1.5 electron-Volt (eV). Implementing the doped semiconductor material 168 as a part of the S/D contact 164 that interfaces at least a portion of the S/D region 114 may provide advantages in terms of reducing the height of a barrier to carrier transport compared to that of an interface between the contact metal 162 of the S/D contact 164 and the S/D region 114.

FIG. 3C illustrates an embodiment where the S/D contact 164 may include a contact metal 162 and a doped semiconductor material 168, as in FIG. 3B, but the doped semiconductor material 168 may be an epitaxially grown material, resulting in a mushroom-like shape of it as shown in the drawing.

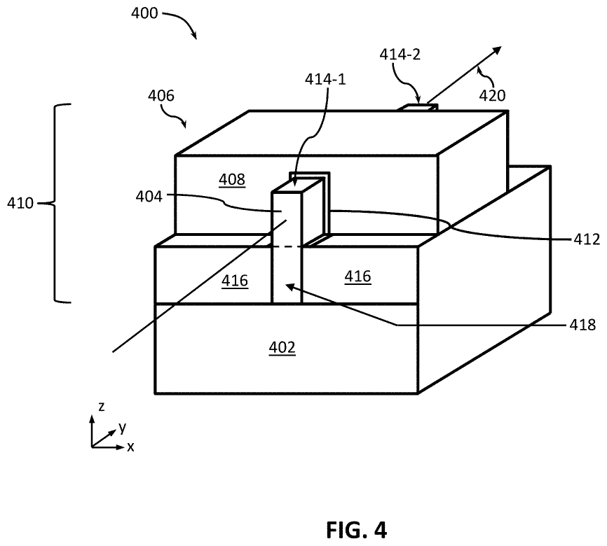

FIG. 4 provides a perspective view of an example IC device 400 implementing a FinFET arrangement with reduced dimensions at the gate, in accordance with some embodiments.

The term “FinFET” refer to a transistor having a non-planar architecture where a fin, formed of one or more semiconductor materials, extends away from a base. FinFETs potentially improve performance relative to planar transistors. In a FinFET, a portion of a fin that is closest to the base is enclosed by a transistor dielectric material. Such a dielectric material, typically an oxide, is commonly referred to as a “shallow trench isolation” (STI), and the portion of the fin enclosed by the STI is referred to as a “subfin portion” or simply a “subfin.” A gate stack that includes at least a layer of a gate electrode metal and, optionally, a layer of a gate dielectric is provided over the top and sides of the remaining upper portion of the fin (i.e., the portion above and not enclosed by the STI), thus wrapping around the upper portion of the fin and forming a three-sided gate of a FinFET. The portion of the fin over which the gate stack wraps around is referred to as a “channel portion” or as an “active region.” FinFETs are sometimes referred to as “tri-gate transistors” because, in use, such transistors may form conducting channels on three “sides” of the channel portion of the fin. A source region and a drain region are provided on either side of the gate stack, forming, respectively, a source and a drain of a FinFET.

Turning to the details of FIG. 4, the IC device 400 may include a semiconductor material, which may include one or more semiconductor materials, formed as a fin 404 extending away from a support structure 402. A FinFET 410 may be formed on the basis of the fin 404 by having a gate stack 406 at least partially wrap around a channel portion of the fin 404 and by having source and drain regions, shown in FIG. 4 as a first S/D region 414-1 and a second S/D region 414-2, on either side of the gate stack 406. As shown in FIG. 4, the gate stack 406 includes a gate electrode material 408 and a gate insulator 412, each of which wraps entirely or almost entirely around the channel portion of the fin 404, although in other embodiments of the IC device 400 the gate insulator 412 may be absent. Descriptions provided above with reference to the support structure 102, the gate stack 106, the gate electrode material 108, the gate insulator 112, and the S/D regions 114 are applicable to, respectively, the support structure 402, the gate stack 406, the gate electrode material 408, the gate insulator 412, and the S/D regions 414, and, therefore, in the interests of brevity, are not repeated. FIG. 4 further illustrates an STI 416, enclosing sidewalls of a subfin portion 418 of the fin 404. The STI 416 may include any of the insulator materials described above, e.g., any suitable ILD materials.

A longitudinal axis 420 of the fin 404 may be along the y-axis of the example coordinate system shown in the present drawings. The FinFET 410 may have a gate length (i.e., a distance between the first and second S/D regions 414-1, 414-2), a dimension measured along the longitudinal axis 420, which may, in some embodiments, be between 2 and 60 nanometers, including all values and ranges therein (e.g., between 5 and 40 nanometers, or between 5 and 30 nanometers). Although the fin 404 is illustrated in FIG. 1 as having a rectangular cross-section in an x-z plane, the fin 404 may instead have a cross-section that is rounded or sloped at the “top” of the fin 404, and the gate stack 406 may conform to this rounded or sloped fin 404. In use, the FinFET 410 may form conducting channels on three “sides” of the fin 404, potentially improving performance relative to single-gate transistors (which may form conducting channels on one “side” of a channel material or substrate) and double-gate transistors (which may form conducting channels on two “sides” of a channel material or substrate).

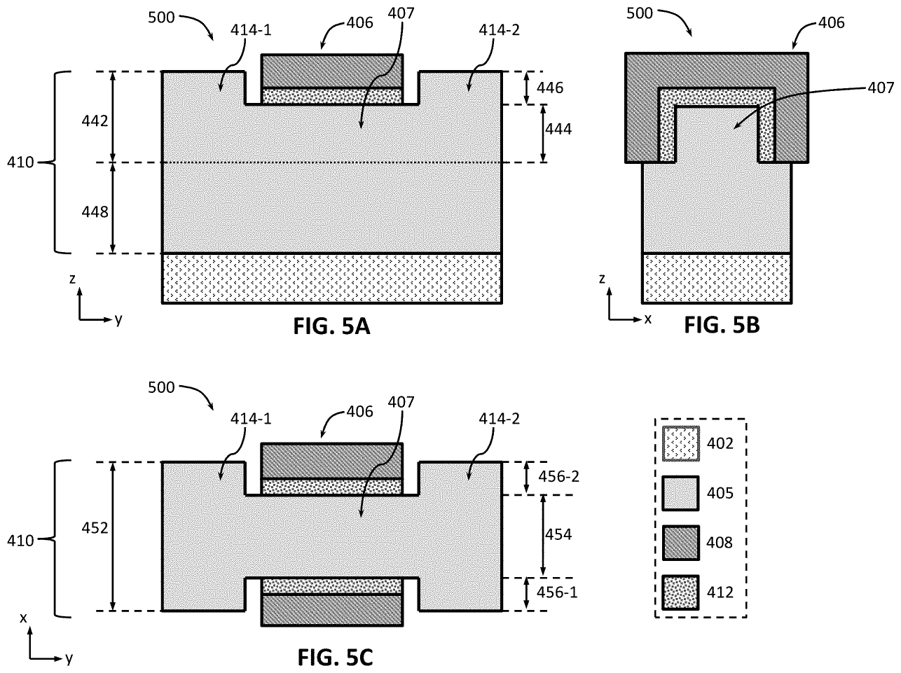

The fin 404 may form a basis for forming a FinFET arrangement with reduced dimensions at the gate, the details of which are explained with reference to FIG. 5A-5C, providing cross-sectional side views and a top-down view of an IC device 500 implementing a FinFET arrangement with reduced dimensions at the gate, in accordance with some embodiments. The IC device 500 may be an example of the IC device 400, shown in FIG. 4. To that end, FIGS. 5A-5C illustrate some of the same reference numerals as those shown in FIG. 4, to indicate similar or analogous elements as those that were described with reference to FIG. 4, so that description of those are not repeated for FIGS. 5A-5C.

As shown in FIG. 5, the FinFET 410 may be built based on a channel material 405, shaped as the fin 404, provided over the support structure 402. Descriptions provided above with reference to the channel material 105 are applicable to the channel material 405, and, therefore, in the interests of brevity, are not repeated. In some embodiments, the subfin portion 418 of the fin 404 may include semiconductor materials of different compositions than the upper portion of the fin 404 (i.e., the portion not enclosed by the STI 416).

Although it is not seen in the perspective view of FIG. 4, the FinFET 410 of the IC device 400 may be an arrangement with reduced dimensions at the gate. This is shown in FIG. 5 with the upper portion of the fin 404, i.e., the portion not enclosed by the STI 416, having a height 442 in some areas but a height 444 in other areas, the height 444 being smaller than the height 442, e.g., less than about 90%, e.g., less than about 85% or less than about 80%, than the height 442. In some embodiments, the height 442 may be a height of the fin 404 in the areas of the S/D regions 414. As such, the height 442 may be referred to as a height of the S/D regions 414. However, in general, the height 442 may be the height of the fin 404 in all portions of the fin 404 except for the channel portions, where an example channel portion 407 of the FinFET is labeled in FIG. 4. Thus, the height 444 may be a height of the fin 404 in the channel portion 407. In some embodiments, the height 442 may be between about 1 and 75 nanometers, including all values and ranges therein, e.g., between about 3 and 50 nanometers or between about 5 and 30 nanometers. The height of the channel portion 407 may be reduced to the height 444 by means of a height reduction 446 at the top of the fin 404 (e.g., by removing a portion of the channel material 405 from the face of the fin 404 that is farthest away from the support structure 402).

Alternatively or additionally to having a reduced height, the FinFET 410 of the IC device 400 may be an arrangement with reduced dimensions at the gate, as shown in FIG. 5 with the fin 404 having a width 452 in some areas but a width 454 in other areas, the width 454 being smaller than the width 452, e.g., less than about 90%, e.g., less than about 85% or less than about 80%, than the width 452. In some embodiments, the width 452 may be a width of the fin 404 in the areas of the S/D regions 414. As such, the width 452 may be referred to as a width of the S/D regions 414. However, in general, the width 452 may be the width of the fin 404 in all portions of the fin 404 except for the channel portions 407. Thus, the width 454 may be a width of the fin 404 in the channel portion 407. In some embodiments, the width 452 may be between about 1 and 75 nanometers, including all values and ranges therein, e.g., between about 3 and 50 nanometers or between about 5 and 30 nanometers. The width of the channel portion 407 may be reduced to the width 454 by means of a width reduction 456-1 at one sidewall of the fin 404 (e.g., by removing a portion of the channel material 405 from the first sidewall of the fin 404) and/or a width reduction 456-2 at another sidewall of the fin 404 (e.g., by removing a portion of the channel material 405 from the second sidewall of the fin 404). In some embodiments, the dimensions of the width reductions 456-1 and 456-2 may be substantially the same, as illustrated in FIG. 5. However, in other embodiments, the dimensions of the width reductions 456-1 and 456-2 may be different and one or both of the width reductions 456-1 and 456-2 may be absent (e.g., the width reductions 456-1 and 456-2 may be absent if reduced dimensions at the gate are achieved by means of only reducing the thickness of the fin 404 at the channel portion 407).

As described above, the IC device 400 shown in the present drawings is intended to show relative arrangements of some of the components therein, and the IC device 400, or portions thereof, may include other components that are not illustrated. For example, while FIG. 5 illustrates only a single FinFET 410 implemented based on the fin 404, in some embodiments, the IC device 500 may include a plurality of FinFETs 410 implemented based on different portions of the fin 404.

In some embodiments, FinFET arrangement with reduced dimensions at the gate may be implemented in memory arrays, such as 1T-1X memory. In other embodiments, a FinFET with reduced dimensions at the gate may be coupled to multiple storage elements, or a FinFET with reduced dimensions at the gate may be coupled to another FinFET or a transistor of any other architecture, to form one or more memory cells of a memory array, all of which being within the scope of the present disclosure.

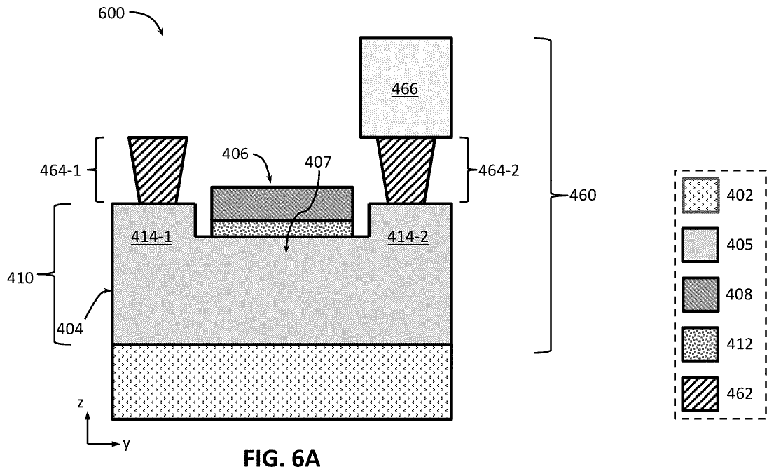

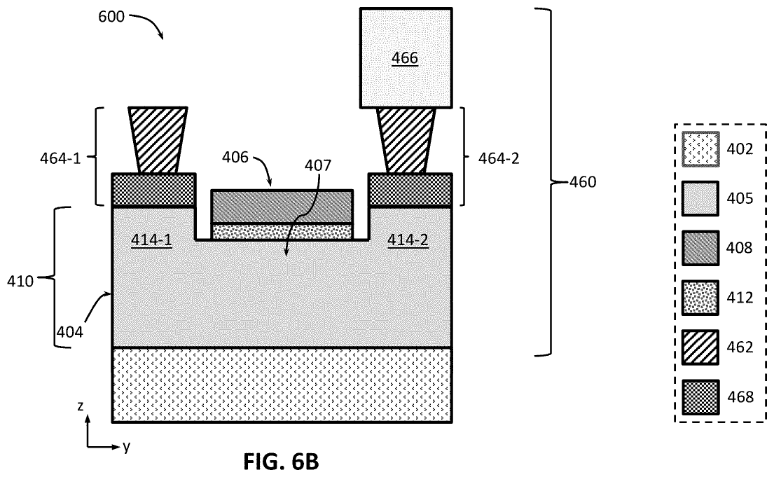

Some examples of 1T-1X FinFET-based memory are illustrated in FIG. 6A-6B, providing cross-sectional side views of an IC device 600 implementing a memory cell 460 that includes a FinFET-based arrangement with reduced dimensions at the gate, in accordance with different embodiments. The IC device 600 may be an example of the IC device 500, shown in FIG. 5. To that end, FIGS. 6A-6B illustrate some of the same reference numerals as those shown in FIG. 5, to indicate similar or analogous elements as those that were described with reference to FIG. 5, so that description of those are not repeated for FIGS. 6A-6B.

As shown in FIGS. 6A-6B, the memory cell 460 may include the FinFET 410 as described above, a first S/D contact 464-1, electrically coupled to (e.g., in electrical/direct contact with) the first S/D region 414-1, a second S/D contact 464-2, electrically coupled to (e.g., in electrical/direct contact with) the second S/D region 414-2, and a storage element 466, electrically coupled to the second S/D contact 464-2. As an example, a DRAM cell may include a storage element 466 in a form of a capacitor for storing a bit value, or a memory state (e.g., logical “1” or “0”) of the cell, and an access transistor, implemented as the FinFET 410 with reduced dimensions at the gate, controlling access to the cell (e.g., access to write information to the cell or access to read information from the cell). Such a memory cell may be referred to as a “1T-1C memory cell.” In other embodiments, the storage element 466 may be any other kind of components capable of storing a memory state, such as a magnetoresistive element, ferroelectric element, or a resistance-changing element. Although not specifically shown in FIGS. 6A-6B, the storage element 466 may be implemented as described with reference to the storage element 166 shown in FIGS. 3A-3C, and may be coupled to the second S/D contact 464-2 as described with reference to coupling the storage element 166 to the second S/D contact 164-2.

FIG. 6A illustrates an embodiment where a given S/D contact 464 may include only a contact metal 462. In such an embodiment, the contact metal 462 of a given S/D contact 464 may be in contact with the respective S/D region 414. Descriptions provided above with reference to the contact metal 162 are applicable to the contact metal 462, and, therefore, in the interests of brevity, are not repeated.

FIG. 6B illustrates an embodiment where the S/D contact 464 may include not only a contact metal 462 but also a doped semiconductor material 468, where the doped semiconductor material 468 of a given S/D contact 464 may be in contact with the respective S/D region 414, and where the contact metal 462 of a given S/D contact 464 may be in contact with the respective doped semiconductor material 468. Descriptions provided above with reference to the doped semiconductor material 168 are applicable to the doped semiconductor material 468, and, therefore, in the interests of brevity, are not repeated.

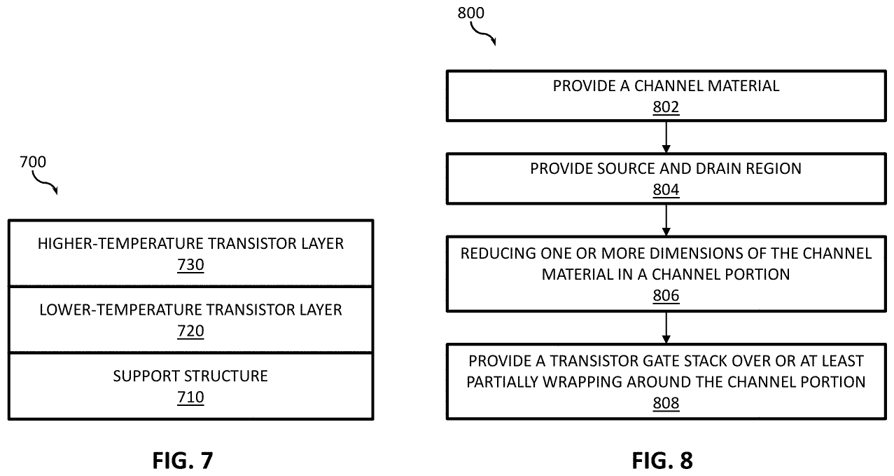

FIG. 7 is a high-level cross-sectional side view of an IC device assembly 700 with transistor layers configured for operation at different temperatures, in accordance with some embodiments. As shown in FIG. 7, the IC device assembly 700 may include a support structure 710, one or more lower-temperature transistor layers 720, and one or more higher-temperature transistor layers 730 so that the one or more lower-temperature transistor layers 720 are between the support structure 710 and the one or more higher-temperature transistor layers 730. The IC device assembly 700 may include any of the embodiments of the IC devices 100, 200, 300, 400, 500, or 600 described with reference to FIGS. 1-6, or any combination of such embodiments, where the support structure 710 may be the support structure 102 or the support structure 402 and any of the lower-temperature transistor layers 720 and/or the higher-temperature transistor layers 730 may include transistors with reduced dimensions at the gate as described above.

The lower-temperature transistor layers 720 may include transistors optimized for operating at relatively low temperatures, e.g., below about 200 Kelvin degrees, while the higher-temperature transistor layers 730 may include transistors optimized for operating at higher temperatures than the transistors of the lower-temperature transistor layers 720, e.g., at room temperature. Such optimization may be in terms of, e.g., choosing the channel material 105/405 (e.g., choosing a semiconductor material with a suitable bandgap), and deciding whether to implement reduced dimensions at the gate according to any embodiments described above. The reasons why FIG. 7 illustrates that the lower-temperature transistor layers 720 may be closer to the support structure 710 than the higher-temperature transistor layers 730 may be as follows. At about room temperature, it may be advantageous to select the channel material 105/405 to be a relatively wider bandgap (e.g., greater than about 1.5 eV) semiconductor material, such as an oxide semiconductor material or any other thin-film semiconductor materials as described above, because semiconductor materials with lower bandgaps may result in too much leakage, compromising the performance of the transistors. On the other hand, at low temperature, oxide semiconductors lose their mobility, to non-oxide semiconductors may be preferable, such as those that may be epitaxially grown on a semiconductor support structure and, hence, the lower-temperature transistor layers 720 may be closer to the support structure 710 than the higher-temperature transistor layers 730. In some embodiments, 2D semiconductor materials such as graphene may be particularly advantageous for use in implementing lower-temperature vs higher-temperature transistors because it is relatively simple to modify their bandgap so that they may be used both for lower-temperature and higher-temperature operation. In some embodiments, the lower-temperature transistor layers 720 may implement transistors with reduced dimensions at the gate according to any embodiments described above, while the higher-temperature transistor layers 730 may implement transistors without reduced dimensions at the gate.

FIG. 8 is a flow diagram of an example method 800 of manufacturing an IC device with one or more transistor arrangements with reduced dimensions at the gate, in accordance with some embodiments. The IC device formed using the method 800 may include any of the embodiments of the IC devices 100, 200, 300, 400, 500, or 600 described with reference to FIGS. 1-6, or any combination of such embodiments. In various embodiments, the method 800 may include other operations not specifically shown in FIG. 8, such as various cleaning or planarization operations as known in the art. For example, in some embodiments, any of the layers of the IC device, or the individual IC structures provided within the IC device, may be cleaned prior to, after, or during any of the processes of the fabrication method described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the top surfaces of the IC devices, or the individual IC structures provided within the IC devices, described herein may be planarized prior to, after, or during any of the processes of the fabrication method described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

As shown in FIG. 8, the fabrication method 800 may include a process 802, that includes providing a channel material. The channel material provided in the process 802 may be the channel material 105/405 as described herein and may be shaped to enable fabrication of transistors of any suitable architecture. In various embodiments, a channel material of the channel layer provided in the process 802 may be provided according to any of the techniques described above with reference to the channel material 105/405, such as layer transfer, direct epitaxial growth, or thin-film deposition.

The method 800 may also include a process 804, that includes providing source and drain regions in the channel layer provided in the process 802. The source and drain regions provided in the process 804 may be the S/D regions 114/414 as described herein. In some embodiments, the process 804 may include providing the S/D regions 114/414 using either an implantation/diffusion process or an etching/deposition process as described above.

The method 800 may further include a process 806, that includes reducing, in the channel portion, one or more dimensions of the channel material provided in the process 802. The reduced dimensions achieved by the process 806 may be as described with reference to the channel portion 107/407.

The method 800 may further include a process 808, that includes providing a transistor gate stack over or at least partially wrapping around the channel portion with one or more reduced dimensions resulting from the process 806. The gate stack provided in the process 808 may be the gate stack 106/406 as described herein.

Although FIG. 8 illustrates that the process 804 is performed before the processes 806 and 808, in various embodiments, the process 804 may be performed after the process 808 or after the process 806.

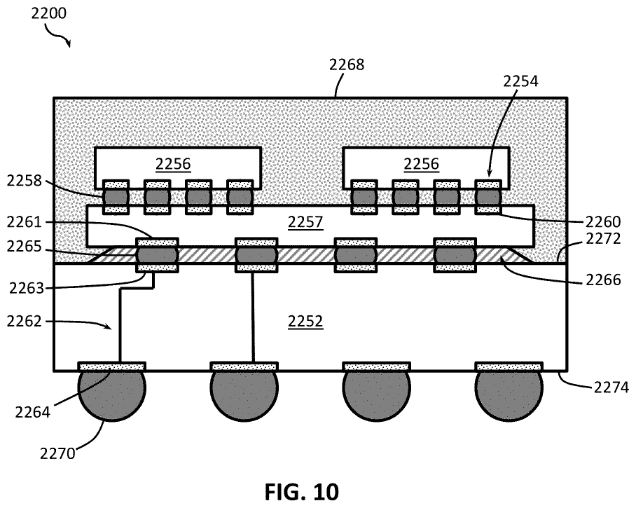

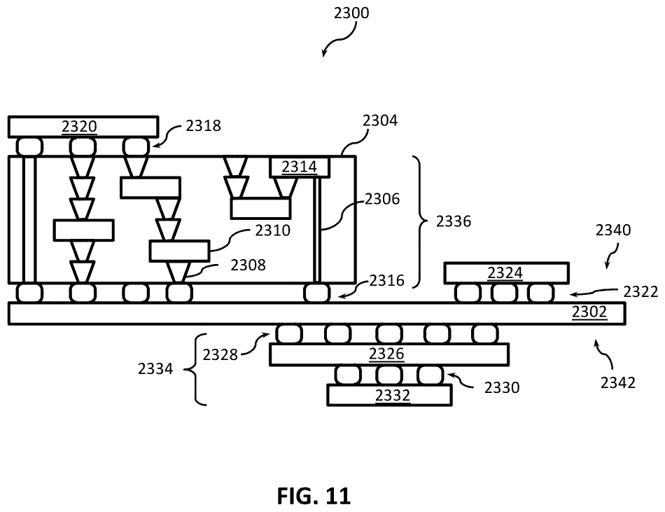

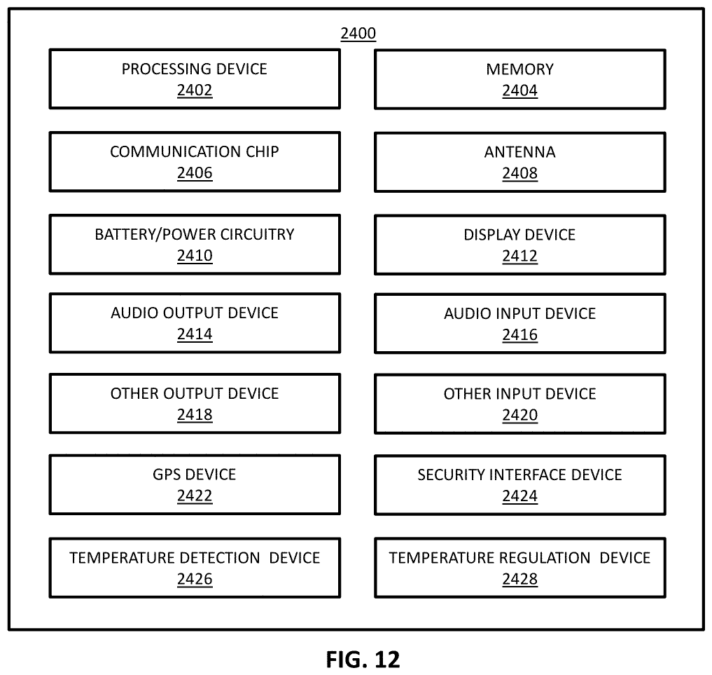

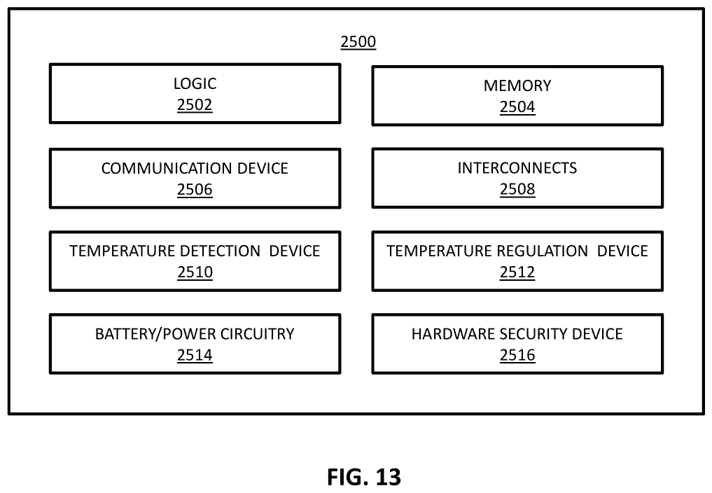

The method 800 may further include processes for fabricating larger device assemblies, e.g., for fabricating an IC package 2200 of FIG. 10, for fabricating an IC device assembly 2300 of FIG. 11, for fabricating a computing device 2400 of FIG. 12, or for fabricating a processing device 2500 of FIG. 13.

The transistor arrangements with reduced dimensions at the gate disclosed herein may be included in any suitable electronic device. FIGS. 9-13 illustrate various examples of devices, packages, and assemblies that may include one or more of the transistor arrangements with reduced dimensions at the gate disclosed herein.

FIG. 9 illustrates top views of a wafer 2000 and dies 2002 that may include one or more IC devices with one or more transistor arrangements with reduced dimensions at the gate in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 10. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more transistor arrangements with reduced dimensions at the gate as described herein). After the fabrication of the semiconductor product is complete (e.g., after manufacture of any embodiment of the IC device 100 as described herein), the wafer 2000 may undergo a singulation process in which each of the dies 2002 is separated from one another to provide discrete “chips” of the semiconductor product. In particular, devices that include one or more transistor arrangements with reduced dimensions at the gate as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., a hysteretic memory device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 10) or other logic that is configured to store information in the memory devices or execute instructions stored in the memory array.

FIG. 10 is a side, cross-sectional view of an example IC package 2200 that may include one or more transistor arrangements with reduced dimensions at the gate in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 10 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 10 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 10 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 11.

The dies 2256 may take the form of any of the embodiments of the die 2002 discussed herein (e.g., may include any of the embodiments of the IC devices with one or more transistor arrangements with reduced dimensions at the gate as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory), including embedded memory dies as described herein. In some embodiments, any of the dies 2256 may include one or more IC devices with one or more transistor arrangements with reduced dimensions at the gate, e.g., as discussed above; in some embodiments, at least some of the dies 2256 may not include any transistor arrangements with reduced dimensions at the gate.

The IC package 2200 illustrated in FIG. 10 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 10, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 11 is a cross-sectional side view of an IC device assembly 2300 that may include components having one or more transistor arrangements with reduced dimensions at the gate in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more transistor arrangements with reduced dimensions at the gate in accordance with any of the embodiments disclosed herein; e.g., any of the IC packages discussed below with reference to the IC device assembly 2300 may take the form of any of the embodiments of the IC package 2200 discussed above with reference to FIG. 10 (e.g., may include one or more transistor arrangements with reduced dimensions at the gate provided on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 11 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 11), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 9), an IC device, or any other suitable component. In particular, the IC package 2320 may include one or more transistor arrangements with reduced dimensions at the gate as described herein. Although a single IC package 2320 is shown in FIG. 11, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 11, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to through-silicon vias (TSVs) 2306. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as radio frequency (RF) devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 11 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 12 is a block diagram of an example computing device 2400 that may include one or more components including one or more IC devices with one or more transistor arrangements with reduced dimensions at the gate in accordance with any of the embodiments disclosed herein. For example, any suitable ones of the components of the computing device 2400 may include a die (e.g., the die 2002 of FIG. 9) having one or more transistors with reduced dimensions as described herein. Any one or more of the components of the computing device 2400 may include, or be included in, an IC package 2200 of FIG. 10 or an IC device 2300 of FIG. 11.

A number of components are illustrated in FIG. 12 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 12, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-M RAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 13 is a block diagram of an example processing device 2500 that may include one or more IC devices with one or more transistor arrangements with reduced dimensions at the gate in accordance with any of the embodiments disclosed herein. For example, any suitable ones of the components of the processing device 2500 may include a die (e.g., the die 2002 of FIG. 9) having one or more transistors with reduced dimensions at the gate as described herein. Any one or more of the components of the processing device 2500 may include, or be included in, an IC device 1400 (FIG. 11). Any one or more of the components of the processing device 2500 may include, or be included in, an IC package 2200 of FIG. 10 or an IC device 2300 of FIG. 11. Any one or more of the components of the processing device 2500 may include, or be included in, a computing device 2400 of FIG. 12; for example, the processing device 2500 may be the processing device 2402 of the computing device 2400.

A number of components are illustrated in FIG. 13 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 13, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 1604 (FIG. 12). In some embodiments, the memory 2504 may be a designated device configured to provide storage functionality for the components of the processing device 2500 (i.e., local), while the memory 1604 may be configured to provide system-level storage functionality for the entire computing device 1600 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, . . . , m₃) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 1606 (FIG. 12). In some embodiments, the communication device 2506 may be a designated device configured to provide communication functionality for the components of the processing device 2500 (i.e., local), while the communication chip 1606 may be configured to provide system-level communication functionality for the entire computing device 1600 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 of FIG. 12 but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 of FIG. 12 but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 of FIG. 12. In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 of FIG. 12. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The above description of illustrated implementations of the disclosure, including what is described in the Abstract, is not intended to be exhaustive or to limit the disclosure to the precise forms disclosed. Unless specified otherwise, in various embodiments, features described with respect to one of the drawings may be combined with those described with respect to other drawings.

The following paragraphs provide various examples of the embodiments disclosed herein.

Example 1 provides a transistor arrangement that includes a channel material including a channel portion; a source region; a drain region; and a transistor gate at least partially wrapping around the channel portion, where the channel portion is a portion of the channel material between the source region and the drain region, and a width of the channel material in the channel portion is smaller than at least one of a width of the source region and a width of the drain region.

Example 2 provides the transistor arrangement according to example 1, where the width of the channel material in the channel portion is less than about 90%, e.g., less than about 85% or less than about 80%, of at least one of the width of the source region and the width of the drain region.

Example 3 provides the transistor arrangement according to any one of examples 1-2, where a thickness/height of the channel material in the channel portion is smaller than at least one of a thickness/height of the source region and a thickness/height of the drain region.

Example 4 provides the transistor arrangement according to example 3, where the thickness/height of the channel material in the channel portion is less than about 90%, e.g., less than about 85% or less than about 80%, of at least one of the thickness/height of the source region and the thickness/height of the drain region.

Example 5 provides the transistor arrangement according to any one of examples 1-4, further including a source contact, electrically coupled to (e.g., in contact with) the source region; and a drain contact, electrically coupled (e.g., in contact with) to the drain region, where the source contact (and/or the drain contact) includes a respective metal.

Example 6 provides the transistor arrangement according to example 5, where the source contact includes a metal and a semiconductor material in contact with the metal, the semiconductor material of the source contact being different from a semiconductor material of the channel portion (e.g., the semiconductor material of the source contact having a material composition different from a material composition of the semiconductor material of the channel portion; and/or analogous may apply to the drain contact/region).

Example 7 provides the transistor arrangement according to any one of examples 5-6, where the source contact includes a metal and a semiconductor material in contact with the metal, the semiconductor material of the source contact having a bandgap that is smaller than a bandgap of a semiconductor material of the channel portion (and/or analogous may apply to the drain contact/region).

Example 8 provides the transistor arrangement according to any one of examples 6-7, where the semiconductor material of the source contact is between the metal and the source region.

Example 9 provides the transistor arrangement according to any one of examples 6-8, where the metal is in contact with the semiconductor material of the source contact and the semiconductor material of the source contact is in contact with the source region.

Example 10 provides the transistor arrangement according to any one of examples 6-9, where the semiconductor material of the source contact has dopants at a concentration of at least about 5×10¹⁸ dopants per cubic centimeter, e.g., at least about 5×10¹⁹ dopants per cubic centimeter or at least about 1×10²¹ dopants per cubic centimeter.

Example 11 provides the transistor arrangement according to example 5, where the metal is in contact with the source region (and/or analogous may apply to the drain contact/region, i.e., another metal may be in contact with the drain region).

Example 12 provides the transistor arrangement according to any one of examples 1-11, where the channel portion includes a semiconductor material having an average grain size larger than about 1 millimeter.

Example 13 provides the transistor arrangement according to any one of examples 1-11, where the channel portion includes a semiconductor material having an average grain size smaller than about 1 millimeter.

Example 14 provides the transistor arrangement according to any one of examples 1-13, where the channel material is a fin or a nanoribbon.

Example 15 provides the transistor arrangement according to any one of examples 1-14, further including a storage element coupled to the source region or the drain region.

Example 16 provides the transistor arrangement according to example 15, where the storage element is one of a capacitor, a magnetoresistive material, a ferroelectric material, or a resistance-changing material.

Example 17 provides an IC package that includes an IC die, the IC die including a transistor arrangement according to any one of the preceding examples (e.g., any one of examples 1-16), e.g., including a nanoribbon or a fin of a semiconductor material, the nanoribbon or a fin including a channel portion, and a gate at least partially wrapping around the channel portion, where at least one dimension of the channel portion of the nanoribbon or the fin is smaller than a corresponding dimension of a portion of the nanoribbon or the fin around which no gate wraps around; and a further component, coupled to the IC die.

Example 18 provides the IC package according to example 17, where the further component is one of a package substrate, an interposer, or a further IC die.

Example 19 provides the IC package according to examples 17 or 18, where the further component is coupled to the IC die via one or more first-level interconnects, where the one or more first-level interconnects include one or more solder bumps, solder posts, or bond wires.

Example 20 provides the IC package according to any one of examples 17-19, where the IC die includes, or is a part of, at least one of a memory device, a computing device, a wearable device, a handheld electronic device, and a wireless communications device.

Example 21 provides an IC device that includes a support structure (e.g., a substrate, a die, a wafer, or a chip); and a transistor arrangement according to any one of the preceding examples (e.g., any one of examples 1-16).

Example 22 provides an electronic device that includes a carrier substrate; and one or more of the transistor arrangements according to any one of the preceding examples and/or the IC package according to any one of the preceding examples and/or the IC device according to any one of the preceding examples, coupled to the carrier substrate.

Example 23 provides the electronic device according to example 22, where the carrier substrate is a motherboard.

Example 24 provides the electronic device according to example 22, where the carrier substrate is a PCB.

Example 25 provides the electronic device according to any one of examples 22-25, where the electronic device is a wearable electronic device (e.g., a smart watch) or handheld electronic device (e.g., a mobile phone).

Example 26 provides the electronic device according to any one of examples 22-25, where the electronic device further includes one or more communication chips and an antenna.

Example 27 provides the electronic device according to any one of examples 22-26, where the electronic device is memory device.

Example 28 provides the electronic device according to any one of examples 22-26, where the electronic device is one of an RF transceiver, a switch, a power amplifier, a low-noise amplifier, a filter, a filter bank, a duplexer, an upconverter, or a downconverter of an RF communications device, e.g., of an RF transceiver.

Example 29 provides the electronic device according to any one of examples 22-26, where the electronic device is a computing device.

Example 30 provides the electronic device according to any one of examples 22-29, where the electronic device is included in a base station of a wireless communication system or in a user equipment device (i.e., a mobile device) of a wireless communication system.

Example 31 provides a method of fabricating an IC device, the method including providing a channel material over a support structure (e.g., a substrate, a die, a wafer, or a chip); providing, in the channel material, a source region and a drain region for a transistor; reducing one or more dimensions of the channel material in a channel portion of the channel material, the channel portion being between the source region and the drain region; and providing a transistor gate over or at least partially wrapping around the channel portion.

Example 32 provides the method according to example 31, further including providing a contact to the source region, the contact including a doped semiconductor material in direct contact with the source region, and a metal in direct contact with the doped semiconductor material.

Example 33 provides the method according to examples 31 or 32, further including processes for fabricating transistor arrangement according to any one of the preceding examples (e.g., any one of examples 1-16).

Example 34 provides the method according to any one of examples 31-33, further including processes for fabricating an IC package according to any one of the preceding examples (e.g., any one of examples 17-20).

Example 35 provides the method according to any one of examples 31-34, further including processes for fabricating an IC package according to any one of the preceding examples (e.g., example 21).

Example 36 provides the method according to any one of examples 31-35, further including processes for fabricating an electronic device according to any one of the preceding examples (e.g., any one of examples 22-30).

1. A transistor arrangement, comprising:
a source region;
a drain region; and
a channel material comprising a channel portion between the source region and the drain region,
wherein a width of the channel material in the channel portion is smaller than at least one of a width of the source region and a width of the drain region.

2. The transistor arrangement according to claim 1, wherein the width of the channel material in the channel portion is less than about 90% of at least one of the width of the source region and the width of the drain region.

3. The transistor arrangement according to claim 1, wherein a thickness of the channel material in the channel portion is smaller than at least one of a thickness of the source region and a thickness of the drain region.

4. The transistor arrangement according to claim 3, wherein the thickness of the channel material in the channel portion is less than about 90% of at least one of the thickness of the source region and the thickness of the drain region.

5. The transistor arrangement according to claim 1, further comprising:
a source contact, electrically coupled to the source region; and
a drain contact, electrically coupled to the drain region,
wherein the source contact includes a metal.

6. The transistor arrangement according to claim 5, wherein the source contact includes a metal and a semiconductor material in contact with the metal, the semiconductor material of the source contact being different from a semiconductor material of the channel portion.

7. The transistor arrangement according to claim 5, wherein the source contact includes a metal and a semiconductor material in contact with the metal, the semiconductor material of the source contact having a bandgap that is smaller than a bandgap of a semiconductor material of the channel portion.

8. The transistor arrangement according to claim 7, wherein the semiconductor material of the source contact is between the metal and the source region.

9. The transistor arrangement according to claim 7, wherein the semiconductor material of the source contact is in contact with the source region.

10. The transistor arrangement according to claim 7, wherein the semiconductor material of the source contact has dopants at a concentration of at least about 5×10²⁰ dopants per cubic centimeter.

11. The transistor arrangement according to claim 5, wherein the metal is in contact with the source region.

12. The transistor arrangement according to claim 1, wherein the channel portion includes a semiconductor material having an average grain size larger than about 1 millimeter.

13. The transistor arrangement according to claim 1, wherein the channel portion includes a semiconductor material having an average grain size smaller than about 1 millimeter.

14. The transistor arrangement according to claim 1, wherein the channel material is a fin or a nanoribbon.

15. The transistor arrangement according to claim 1, further comprising:
a storage element coupled to the source region or the drain region.

16. The transistor arrangement according to claim 15, wherein the storage element is one of a capacitor, a magnetoresistive material, a ferroelectric material, or a resistance-changing material.

17. An integrated circuit (IC) package, comprising:
an IC die, comprising:
a nanoribbon comprising a channel portion, and
a gate at least partially wrapping around the channel portion,
wherein at least one dimension of the channel portion of the nanoribbon is smaller than a corresponding dimension of a portion of the nanoribbon around which no gate wraps around; and
a further component, coupled to the IC die.

18. The IC package according to claim 17, wherein the further component is one of a package substrate, an interposer, or a further IC die.

19. A method of fabricating an integrated circuit (IC) device, the method comprising:
providing a channel material over a support structure;
providing, in the channel material, a source region and a drain region for a transistor;
reducing one or more dimensions of the channel material in a channel portion of the channel material, the channel portion being between the source region and the drain region; and
providing a transistor gate over or at least partially wrapping around the channel portion.

20. The method according to claim 19, further comprising providing a contact to the source region, the contact comprising a doped semiconductor material in direct contact with the source region, and a metal in direct contact with the doped semiconductor material.
